(19) United States
(12) Patent Application Publication
(10) Pub. No.: US 2022/0078950 A1
(43) Pub. Date: Mar. 10, 2022

(54) HONEYCOMB STRUCTURE AND METHOD FOR MANUFACTURING HONEYCOMB STRUCTURE

(71) Applicant: MITSUBISHI HEAVY INDUSTRIES, LTD., Tokyo (JP)

(72) Inventors: Yoshiaki ARAKAWA, Tokyo (JP); Takashi IKEDA, Tokyo (JP); Akio IKEDA, Tokyo (JP); Hisashi SHIMIZU, Tokyo (JP); Jun KURODA, Tokyo (JP); Syusaku YAMAMOTO, Tokyo (JP); Masashi KITAMURA, Tokyo (JP); Shuji TANIGAWA, Tokyo (JP); Daishi SUMI, Tokyo (JP)

(21) Appl. No.: 17/464,125

(22) Filed: Sep. 1, 2021

(30) Foreign Application Priority Data
Sep. 4, 2020 (JP) 2020-148801

(51) Int. Cl. H05K 9/00

(52) U.S. Cl. CPC H05K 9/0007

(57) ABSTRACT

A honeycomb structure includes an incoming end having a concave shape; an outgoing end having a convex shape; and a plurality of cells each having a polygonal cross section and serving as a channel for a fluid, the channel extending from the incoming end to the outgoing end. The plurality of cells are separated from each other by separator walls. At least one of the plurality of cells has an area of a channel cross section perpendicular to a longitudinal direction, the area increasing from the incoming end toward the outgoing end.

### CROSS-REFERENCE TO RELATED APPLICATIONS

The present application claims priority to and incorporates by reference the entire contents of Japanese Patent Application No. 2020-148801 filed in Japan on Sep. 4, 2020.

### FIELD

The present invention relates to a honeycomb structure and a method for manufacturing a honeycomb structure.

### BACKGROUND

Recently, as a technical issue to be addressed in relation to a high electromagnetic pulse (EMP) defense technology, in order to protect electronic devices from strong electromagnetic waves, there has been a demand for a protective measure adapted to the nature of the electromagnetic waves that impose a threat. Specifically, some protective measures against high EMPs and high output microwaves are required in an opening of a ventilation duct, a cooling duct, or the like, in critical facilities such as power plants, data centers, and defense facilities.

### CITATION LIST

### Patent Literature

Patent Literature 1: Japanese Patent Application Laid-open No. H11-81518

### SUMMARY

### Technical Problem

In order to ensure shielding performance against electromagnetic waves at 10 GHz, which is the frequency assumed for high EMPs, it is necessary to set the width of an opening of a channel to a size equal to or smaller than a half the wavelength of the electromagnetic wave of 30 mm, that is, to a size equal to or smaller than 15 mm. However, because a conventional opening structure with slits, such as those in a duct or a louver structure in a critical facility, has a slit width equal to or greater than 15 mm, such openings permit easy entry of the electric fields. By contrast, with a commercially available electromagnetic shield having a honeycomb structure (such as that disclosed in Patent Literature 1), not only auxiliary machinery power may be increased due to a pressure loss caused by the airflow, but also such electromagnetic shields can only be installed on a flat surface. Therefore, it has been difficult to fit into the openings with shapes that are different among the facilities.

The present invention is made in consideration of the above, and an object of the present invention is to provide a honeycomb structure and a method for manufacturing a honeycomb structure that are capable of not only ensuring the shielding performance but also suppressing a pressure loss.

### Solution to Problem

A honeycomb structure according to the present disclosure includes an incoming end having a concave shape; an outgoing end having a convex shape; and a plurality of cells each having a polygonal cross section and serving as a channel for a fluid, the channel extending from the incoming end to the outgoing end. The plurality of cells are separated from each other by separator walls, and at least one of the plurality of cells has an area of a channel cross section perpendicular to a longitudinal direction, the area increasing from the incoming end toward the outgoing end.

Further, a honeycomb structure according to the present disclosure is made from an assembly of a plurality of polygonal prism-shaped cells having a polygonal cross section in which a passage in a longitudinal direction is provided. A side face of one of the plurality of polygonal prism-shaped cells and a side face of another polygonal prism-shaped cell adjacent to the one of the plurality of polygonal prism-shaped cells integrally form a separator wall. At least one of the plurality of polygonal prism-shaped cells has an area of the cross section, the area increasing from one end toward another end of the at least one of the plurality of polygonal prism-shaped cells in the longitudinal direction. A surface of the one end and a surface of the other end of the assembly in the longitudinal direction are curved toward a direction opposite to a direction in which the area increases.

Further, in a method for manufacturing the honeycomb structure according to the present disclosure, a 3D printer additively lays layers, with a protrusion that is to be on a side of the outgoing end as a base, toward the incoming end, so as to manufacture the honeycomb structure.

### Advantageous Effects of Invention

According to the present invention, an object of the present invention is to provide a honeycomb structure and a method for manufacturing a honeycomb structure capable of not only ensuring the shielding performance but also suppressing a pressure loss.

### BRIEF DESCRIPTION OF DRAWINGS

FIG. 1 is a perspective view schematically illustrating a part of a honeycomb structure according to an embodiment.

FIG. 2 is a perspective view schematically illustrating one of the cells in the honeycomb structure illustrated in FIG. 1.

FIG. 3 is a table indicating the dimensions of the cell illustrated in FIG. 2.

FIG. 4 is a cross-sectional view illustrating the honeycomb structure according to the embodiment.

FIG. 5 is a perspective view schematically illustrating a shield structure in a first application mode that is an application of the honeycomb structure according to the embodiment.

FIG. 6 is a sectional view illustrating a honeycomb structure according to a first modification.

FIG. 7 is a perspective view schematically illustrating a shield structure in a second application mode that is an application of the honeycomb structure according to the first modification.

FIG. 8 is a perspective view of the shield structure illustrated in FIG. 7 seen from another direction.

FIG. 9 is a graph indicating a ratio of a pressure loss in the shield structure in the second application mode, with respect to that in a comparative example.

FIG. 10 is a sectional view illustrating a honeycomb structure according to a second modification.

FIG. 11 is a sectional view illustrating a honeycomb structure according to a third modification.

FIG. 12 is a sectional view illustrating a honeycomb structure according to a fourth modification.

FIG. 13 is a sectional view illustrating a honeycomb structure according to a fifth modification.

### DESCRIPTION OF EMBODIMENTS

A honeycomb structure and a method for manufacturing a honeycomb structure according to an embodiment of the present invention will now be explained in detail based on some drawings. The scope of the present invention is, however, not limited to the description of the embodiment. Furthermore, the elements described in the embodiment below include elements that are easily replaceable by those skilled in the art, elements that are substantially the same, or elements falling within the scope of equivalency. Furthermore, the elements described in the embodiment may be omitted, replaced, or modified variously, within the scope not deviating from the essence of the present invention. In the embodiment described below, the elements required in describing examples of the embodiment of the shock wave supply device according to the present invention will be explained, and explanations of the other elements will be omitted. In the explanation of the embodiment below, the same structures will be given the same reference numerals, and different structures will be given different ones.

### Embodiments

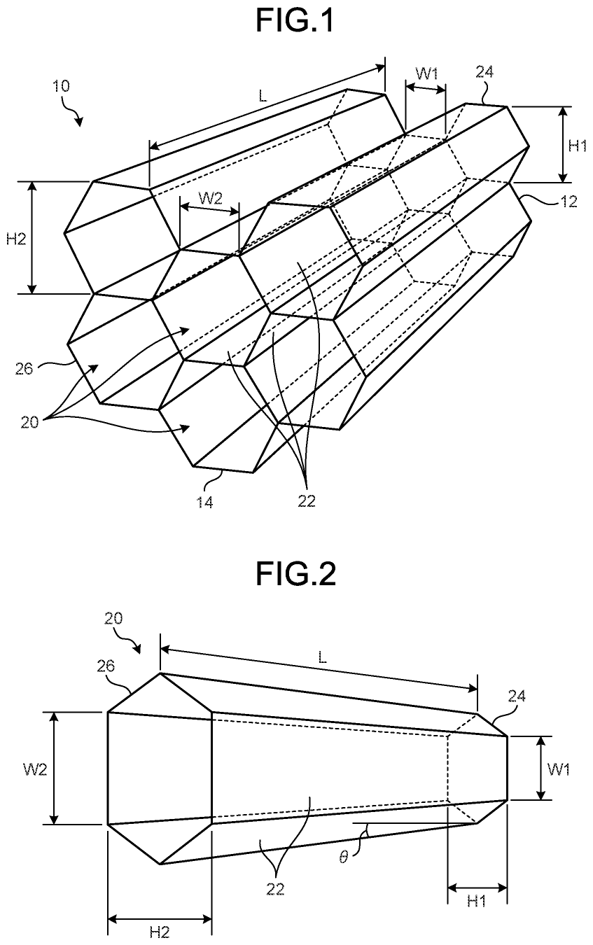

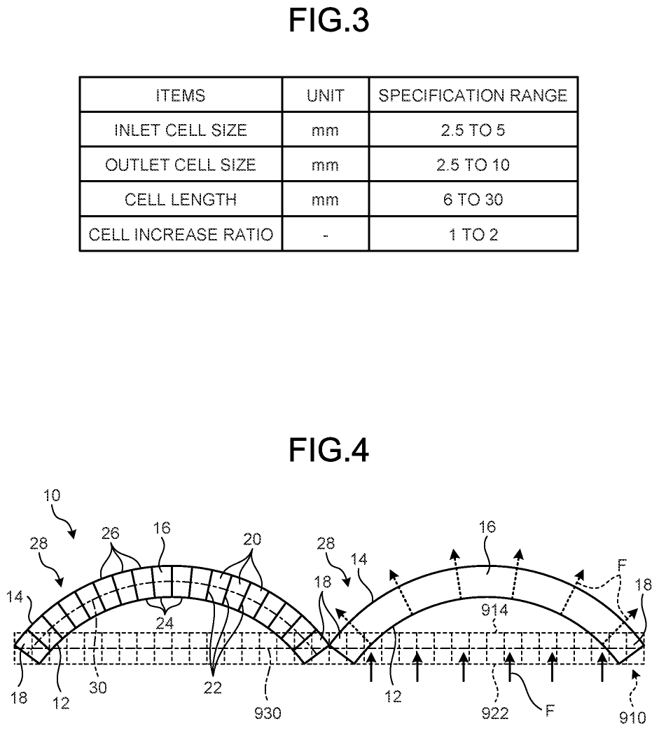

To begin with, a configuration of a honeycomb structure 10 according to one embodiment will now be explained. FIG. 1 is a perspective view schematically illustrating a part of the honeycomb structure 10 according to the embodiment. FIG. 2 is a perspective view schematically illustrating a cell 20 in the honeycomb structure 10 illustrated in FIG. 1. FIG. 3 is a table indicating the dimensions of the cell 20 illustrated in FIG. 2. FIG. 4 is a cross-sectional view illustrating the honeycomb structure 10 according to the embodiment.

The honeycomb structure 10 is applied to a structure or equipment requiring not only shielding between an inlet and an outlet of a channel but also suppressing of the pressure loss in a fluid passing through the channel. The honeycomb structure 10 is applied to an electromagnetic shield for defending against entry of electromagnetic waves via an opening of a critical facility such as a power plant, a data center, or a defense facility, or to a heat exchanger, for example.

As illustrated in FIG. 1, the honeycomb structure 10 includes a plurality of cells 20 serving as a channel (passage) for a fluid, the channel extending from an incoming end 12 to an outgoing end 14. Each of the cells 20 has a polygonal tubular shape on a cross section (hereinafter, referred to as a channel cross section) that is perpendicular to the longitudinal direction. In other words, the cell 20 is a cell having a shape of a hollow polygonal prism with a polygonal cross sectional shape, and the honeycomb structure 10 is an assembly of a plurality of the cells each having a polygonal prism shape. The channel cross sectional shape of the cell 20 is regular hexagonal in the embodiment, but may also be triangular, rectangular, octagonal, or any desired combinations thereof.

Adjacent ones of the cells 20 are separated from one another by separator walls 22 provided in a manner surrounding the spaces inside the cells 20. A side face of the cell 20 and a side face of another adjacently positioned cell 20 integrally form a separator wall 22. In other words, a cell 20 and another cell 20 adjacent thereto share a separator wall 22, with the separator wall 22 positioned therebetween. The separator wall 22 has a plate with a flat shape and a constant thickness.

As illustrated in FIG. 2, the cell 20 has an incoming opening 24 and an outgoing opening 26. The incoming opening 24 is one end of the cell 20 in the longitudinal direction, and opens to the side of the incoming end 12 of the honeycomb structure 10. The outgoing opening 26 is another end of the cell 20 in the longitudinal direction, and opens to the outgoing end 14 of the honeycomb structure 10.

The width of the cell 20 becomes larger from one end toward the other end in the longitudinal direction. More specifically, the cell 20 has a tapered tubular shape in which the channel cross sectional area increases from the incoming opening 24 toward the outgoing opening 26. In the embodiment, the shape of the cell 20 has a linearly increasing width so that the angle formed by a direction parallel with the longitudinal direction and a side edge of the separator wall 22 is a constant increasing angle θ. In other words, the separator wall 22 of the cell 20 has a shape of an isosceles trapezoid with a base having a width W1 on the side of the incoming opening 24, another base having a width W2 larger than the width W1 on the side of the outgoing opening 26, and two legs having a length L.

The honeycomb structure 10 according to the embodiment includes the cells 20 the all of which have the same shape, but may also include a plurality of types of cells 320 having different shapes, in the same manner as in a honeycomb structure 210 according to a second modification, which will be described later, for example. The honeycomb structure may also include some cells 420 having a straight shape in which the cross sectional area from the incoming opening 424 to the outgoing opening 426 is constant, instead of the tapered tubular shape, in the same manner as in a honeycomb structure 410 according to a fourth modification, which will be described later.

FIG. 3 indicates an example of the range of the dimensions of the cells 20 capable of achieving an electromagnetic shielding performance of 80 dB at 10 GHz in the embodiment. The electromagnetic shielding performance can be adjusted using an average between the inlet cell size and the outlet cell size, and the cell length. When a different electromagnetic shielding performance is required, the ranges of these specifications change, and therefore, the specifications may fall outside of the ranges indicated in FIG. 3.

In FIG. 3, the distance H1 between the facing separator walls 22 of a cell 20 at the incoming opening 24 will be referred to as an “inlet cell size”. The inlet cell size is set to a range equal to or more than 2.5 mm and equal to or less than 5 mm. The distance H2 between the facing separator walls 22 of a cell 20 at the outgoing opening 26 will be referred to as an “outlet cell size”. The outlet cell size is set to a range equal to or more than 2.5 mm and equal to or less than 10 mm. The length L of the legs of the separator wall 22 will be referred to as a “cell length”. The cell length is set to a range equal to or more than 6 mm and equal to or less than 30 mm. The ratio of the outlet cell size with respect to the inlet cell size will be referred to as a “cell increase ratio”. In other words, the cell increase ratio is an increase ratio of a width of the channel cross section from the incoming opening 24 that opens to the incoming end 12 to the outgoing opening 26 that opens to the outgoing end 14. The cell increase ratio is set to a range equal to or more than one and equal to or less than two.

In FIG. 4, a honeycomb structure 910 having a flat incoming end 912 and outgoing end 914 is illustrated in dotted lines, as a comparative example, in addition to the honeycomb structure 10 according to the embodiment. The cell 20 according to the embodiment has a tapered tubular shape in which a cross sectional area perpendicular to the longitudinal direction increases from the incoming opening 24 toward the outgoing opening 26, as described earlier. Because the honeycomb structure 10 has a structure in which the cells 20 are connected one after another via the separator walls 22, as illustrated in FIG. 4, the honeycomb structure 10 has a shape with the incoming end 12 having a concave shape and the outgoing end 14 having a convex shape, with these ends curved in the same direction that is the direction opposite to the direction of the width increase. In other words, the honeycomb structure 10 includes a cross section having a fan-like shape in a direction parallel with the channel. In the honeycomb structure 10 according to the embodiment, the incoming end 12 and the outgoing end 14 are curved as a whole in the same direction, but these surfaces may also have a part that is not curved as in a honeycomb structure 410 according to a fourth modification, which will be described later.

The honeycomb structure 10 protrudes the furthest at a central part 16 thereof in the channel cross section direction on the outgoing end 14 side. The honeycomb structure 10 may be provided with a plurality of cell groups 28 connected to each other in a fan-like cross section so that the cell groups 28 are arranged continuously, in accordance with the shape of the opening where the honeycomb structure 10 is installed, as illustrated in FIG. 4, for example. Each of the cell groups 28 is connected to an adjacent cell group 28 on their respective ends 18 in the channel cross section direction. More specifically, the separator wall 22 of the cell 20 at one end 18 of a cell group 28, that is, the separator wall 22 not shared by any other cells 20 is connected, with the edge on the outgoing openings 26 side thereof, to the edge on the outgoing openings 26 side of the separator wall 22 of the cell 20 at one end 18 of the adjacent cell group 28. In this manner, the fluid F passes through the inside of the cells 20 from the incoming end 12 toward the outgoing end 14, and does not flow out from other than the cell 20.

In the right half of the honeycomb structure 10 illustrated in FIG. 4, the separator walls 22 of the cells 20 are not illustrated, but the directions in which the fluid F passing through the cells 20 flows are indicated. The directions of the flow of the fluid F passing through the cells 20 of the honeycomb structure 10 are radial directions spreading correspondingly to the fan-like shape.

In the honeycomb structure 10 according to the embodiment, a channel area 30 increases from the incoming end 12 toward the outgoing end 14. In the honeycomb structure 10, because the flow velocity of the fluid F passing through the cells 20 decreases as the channel area 30 increases, the pressure loss is suppressed. The honeycomb structure 10 according to the embodiment has a larger channel area 30 than the channel area 930 of the honeycomb structure 910 in the comparative example. Therefore, the honeycomb structure 10 having a convex outgoing end 14 can suppress the pressure loss compared to the honeycomb structure 910 having a flat incoming end 912 and outgoing end 914.

It is preferable for the honeycomb structure 10 according to the embodiment to be manufactured by a 3D printer for metals, for example. It is also possible to manufacture the honeycomb structure 10 by forming the structure using a 3D printer for resins or by extruding, and then by applying conductive coating thereto, or by plating. When a 3D printer is used in the manufacture, a base is manufactured on an area vertically below where the honeycomb structure 10 to be formed, and a structure that is to become the honeycomb structure 10 is then formed on the base. At this time, the honeycomb structure 10 is manufactured by additively laying layers on a protrusion provided on the side of the outgoing end 14 as a base, toward the incoming end 12. In this manner, it is possible to form the separator walls 22 each separating adjacent cells 20 so that each separator wall 22 interposed therebetween is shared by the adjacent cells 20. In this manner, a good electrical connection is achieved in a portion where the adjacent cells 20 are joined, so that it is possible to prevent entry of high EMPs. Furthermore, it is possible to form the separator walls 22 so as to have a uniform thickness. In this manner, the inner walls of the cells 20 are kept flat, and the pressure loss of the fluid F passing through the cells 20 can be suppressed.

First Application Mode

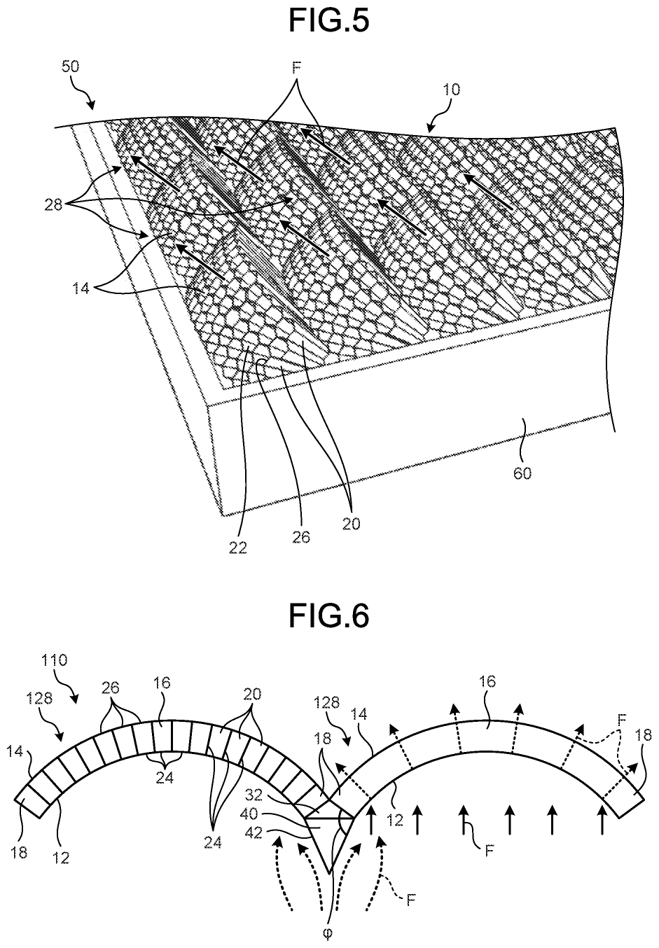

FIG. 5 is a perspective view schematically illustrating a shield structure 50 in a first application mode that is an application of the honeycomb structure 10 according to the embodiment. The shield structure 50 is provided inside a rectangular frame 60 corresponding to an opening of a critical facility. The shield structure 50 includes a plurality of cell groups 28 provided in such an orientation that the directions of the flows of the fluid F, that is, the longitudinal directions of the cells 20 are inclined with respect to the direction of the opening of the frame 60. The cell groups 28 are arranged in rows along one direction that is in parallel with one side of the rectangular frame 60. The cell groups 28 are arranged in a stair-like shape in the other direction that is perpendicular to the one direction, in the frame 60.

### First Modification

A configuration of a honeycomb structure 110 according to a first modification will now be explained. FIG. 6 is a cross-sectional view illustrating the honeycomb structure 110 according to the first modification. In FIG. 6, the parts that are the same as those according to the embodiment will be given the same reference numerals, and explanations thereof will be omitted. Furthermore, in the right half of the honeycomb structure 110 illustrated in FIG. 6, the separator walls 22 of the cells 20 are not illustrated, but the directions in which the fluid F passing through the cells 20 flows are indicated.

The honeycomb structure 110 according to the first modification is different from the honeycomb structure 10 according to the embodiment in having a straightening vane 40. The straightening vane 40 is provided in a dead space 32 that is a space surrounded by the separator walls 22 of the cells 20 at the ends 18 of the adjacent cell groups 28. The straightening vane 40 is provided on the separator walls 22 located at the connection between the adjacent cell groups 28, in a manner projecting from the incoming end 12. The straightening vanes 40 are provided along the ends 18 of the cell groups 28 (along the direction perpendicular to the paper surface in FIG. 6). The straightening vane 40 has a reversed triangular cross section in a direction perpendicular to the longitudinal direction.

The straightening vane 40 has receiving surfaces 42 that are connected to the incoming end 12. It is preferable for a straightening angle φ formed by the end 18 of the receiving surface 42 and the separator wall 22 of the cell 20 to be equal to or more than 100 degrees. The straightening vane 40 receives the fluid F on the receiving surfaces 42, so as to prevent the fluid F from flowing into the dead space 32 that is the space surrounded by the separator walls 22 of the cells 20 at the ends 18 of the adjacent cell groups 28. In this manner, it is possible to suppress curving, which is caused by a flow of the fluid F near the end 18 of the cell group 28 in the honeycomb structure 110, of other main flows of the fluid F.

Second Application Mode

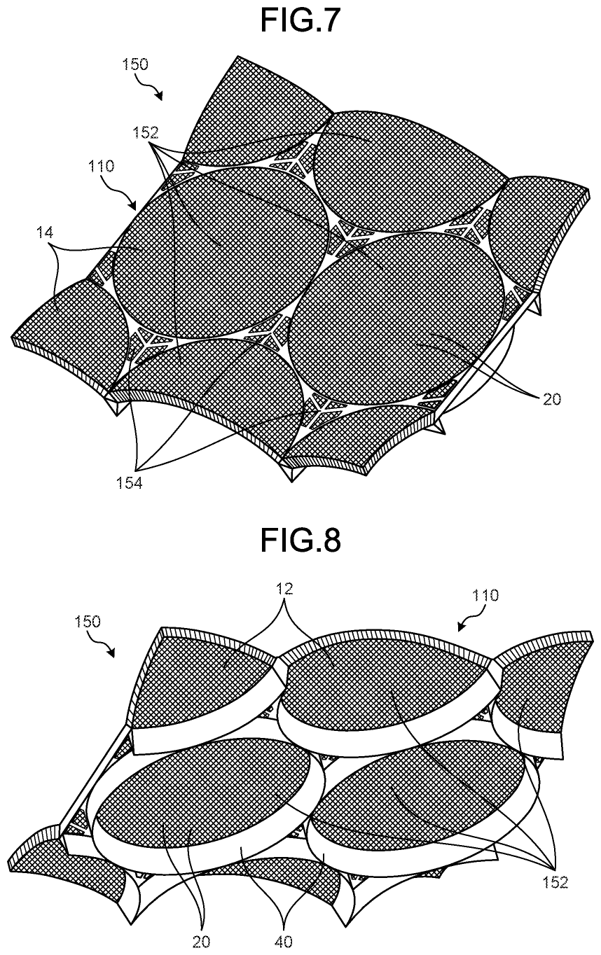

FIG. 7 is a perspective view schematically illustrating a shield structure 150 in a second application mode that is an application of the honeycomb structure 110 according to the first modification. FIG. 8 is a perspective view of the shield structure 150 illustrated in FIG. 7 seen from another direction. In FIGS. 7 and 8, the incoming openings 24 and the outgoing openings 26 of the cells 20 on the incoming end 12 and the outgoing end 14 are illustrated in a simplified manner as a grid pattern. As illustrated in FIGS. 7 and 8, the shield structure 150 includes a plurality of dome portions 152 and inter-dome portions 154.

The honeycomb structure 110 according to the first modification is applied to the dome portion 152. The dome portion 152 has a hemispheric shape formed by connecting the cells 20 evenly in the channel cross section direction. The dome portion 152 has a dome shape in which the incoming end 12 has a concave spherical surface, and the outgoing end 14 has a convex spherical surface. The straightening vanes 40 are provided along the ends 18 of the dome portions 152 on the incoming end 12 (see FIG. 6). The straightening vane 40 is provided in a ring-like shape along the end 18 of the dome portion 152.

The inter-dome portion 154 is a space surrounded by the edges of the three dome portions 152. The inter-dome portion 154 is formed by the cells 20 connected to one another, in the same manner as the dome portion 152. Arranged in the inter-dome portion 154 are not only the cells 20 with a tapered tubular shape having an increasing width from the incoming opening 24 toward the outgoing opening 26, the tapered tubular shape being the same as that according to the embodiment, but also cells with a straight shape having a channel cross section whose area is constant across a range from the incoming opening to the outgoing opening.

The shield structure 150 is a structure in which a plurality of hexagonal structures each having the corresponding dome portion 152 are connected to one another, via the side faces of the hexagons. In other words, the inter-dome portions 154 correspond to the corners of the hexagons.

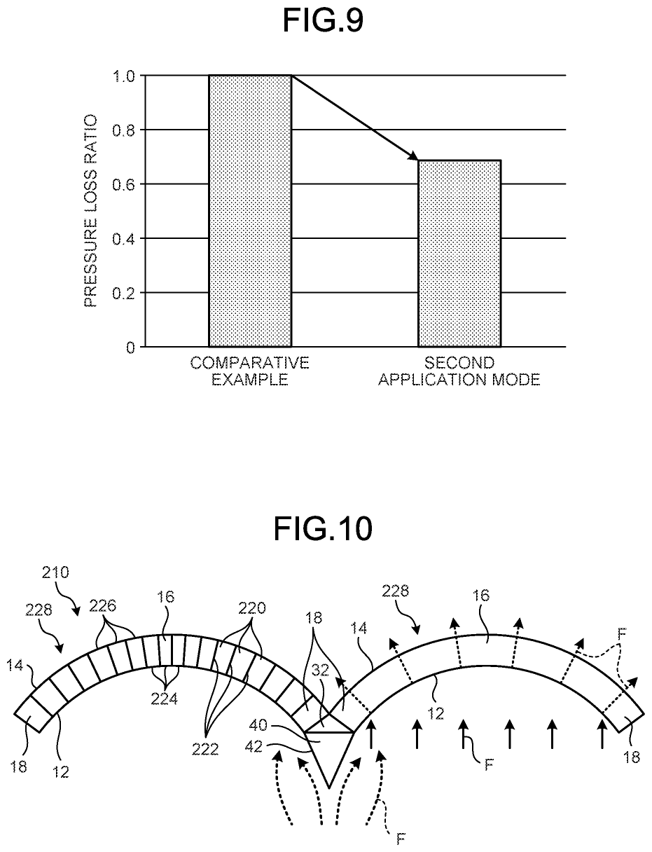

FIG. 9 is a graph indicating a ratio of a pressure loss in the shield structure 150 in the second application mode, with respect to that in a comparative example. The shield structure in the comparative example is a structure using a honeycomb structure 910 according to the comparative example illustrated in FIG. 4, instead of the honeycomb structure 110 according to the first modification. In other words, in the shield structure in the comparative example, the incoming end 912 and the outgoing end 914 of the honeycomb structure 910 are flat.

In the shield structure 150 having the dome-shaped honeycomb structure 110 in the second application mode, the pressure loss of the fluid F passing through the cells 20 is approximately 30 percent less than that passing through the cells 920 in the shield structure with the flat honeycomb structure 910 according to the comparative example, as illustrated in FIG. 9. In this manner, in the shield structure 150 in the second application mode, the pressure loss is suppressed because the flow velocity of the fluid F passing through the cells 20 decreases as the channel area increases from the incoming end 12 toward the outgoing end 14 of the honeycomb structure 110 in the dome portion 152. Furthermore, the straightening vanes 40 provided to the ends 18 of the respective dome portions 152 on the side of the incoming end 12 receive the fluid F, thereby further suppressing the pressure loss.

### Second Modification

A configuration of a honeycomb structure 210 according to a first modification will now be explained. FIG. 10 is a cross-sectional view illustrating the honeycomb structure 210 according to the second modification. In FIG. 10, the parts that are the same as those according to the first modification will be given the same reference numerals, and explanations thereof will be omitted. Furthermore, in the right half of the honeycomb structure 210 illustrated in FIG. 10, the separator walls 222 of the cells 220 are not illustrated, but the directions in which the fluid F passing through the cells 220 flows are indicated.

The honeycomb structure 210 according to the second modification has the incoming end 12 having a concave shape and the outgoing end 14 having a convex shape, in the same manner as the honeycomb structure 10 according to the embodiment and the honeycomb structure 110 according to the first modification. In the second modification, the curvatures of the incoming end 12 and the outgoing end 14 of the honeycomb structure 210 are the same as those of the incoming end 12 and the outgoing end 14 according to the embodiment and the first modification.

The honeycomb structure 210 according to the second modification is different from the honeycomb structure 110 according to the first modification in including cells 220 instead of the cells 20. In the cells 220, adjacent cells 220 are separated from one another by the separator walls 222, in the same manner as in the cells 20 according to the embodiment and the first modification.

The cell 220 has an incoming opening 224 that opens to the incoming end 12, and an outgoing opening 226 that opens to the outgoing end 14. The honeycomb structure 210 is provided with a plurality of cell groups 228 connected to each other in a fan-like cross section so that the cell groups 228 are arranged continuously, in the same manner as in the honeycomb structures 10, 110 according to the embodiment and the first modification.

In the honeycomb structure 210, among the cells 220, cells 220 positioned in the central part 16 of the cell group 228 in the channel cross section direction have different sizes from those of the cells 220 positioned near the ends 18. More specifically, the cells 220 positioned near the ends 18 have larger channel cross sectional areas than the cells 220 positioned in the central part 16. Furthermore, the cells 220 positioned near the ends 18 has higher increase ratios of the channel cross sectional width from the incoming end 12 to the outgoing end 14, than the cells 220 positioned in the central part 16.

In the honeycomb structure 210 having the outgoing end 14 protruding in a concave shape, the fluid F becomes collected at the central part 16, and does not easily flow into the end 18. In the second modification, setting the increase ratio of the channel cross sectional area and the increase ratio of the width for the cells 220 of the end 18 higher than the central part 16 suppresses the differences in the flow velocities of the fluid F on the incoming end 12. Allowing the fluid F to flow at a constant velocity across the entire cell groups 228 can suppress the pressure loss.

### Third Modification

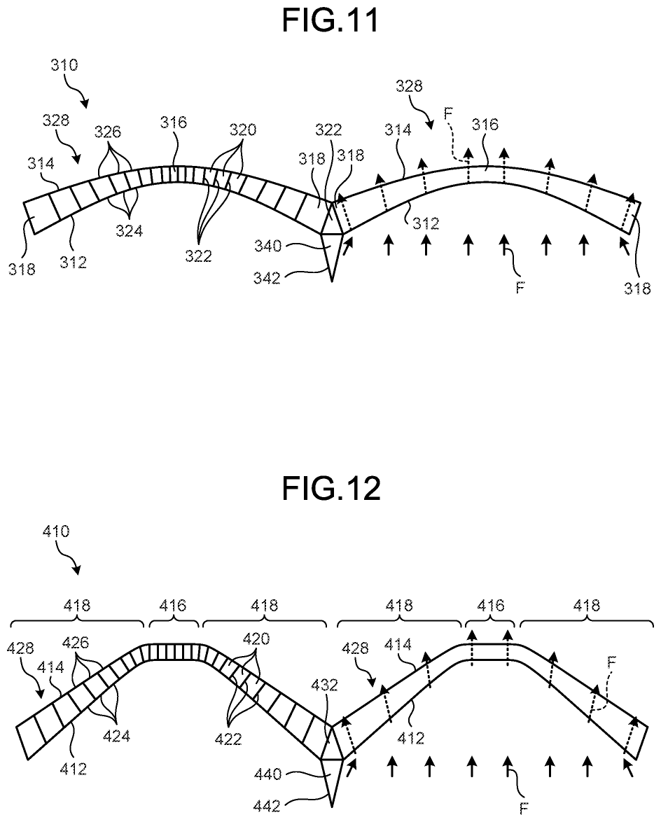

A configuration of a honeycomb structure 310 according to a third modification will now be explained. FIG. 11 is a cross-sectional view illustrating the honeycomb structure 310 according to the third modification. In the right half of the honeycomb structure 310 illustrated in FIG. 11, the separator walls 322 of the cells 320 are not illustrated, but the directions in which the fluid F passing through the cells 320 flows are indicated.

The honeycomb structure 310 according to the third modification has an incoming end 312 having a concave shape, and an outgoing end 314 having a convex shape. The honeycomb structure 310 according to the third modification includes a plurality of cells 320 and a straightening vane 340 instead of the cells 220 and the straightening vane 40, which is difference from the honeycomb structure 210 according to the second modification. Adjacent cells 320 of the cells 320 are separated from one another by the separator walls 322 in the same manner as the cells 20, 220 in the embodiment, the first modification, and the second modification.

The cell 320 has an incoming opening 324 that opens to the incoming end 312, and an outgoing opening 326 that opens to the outgoing end 314. The honeycomb structure 310 is provided with a plurality of cell groups 328 connected to each other in a fan-like cross section so that the cell groups 328 are arranged continuously, in the same manner as in the honeycomb structure 10, 110, 210 according to the embodiment, the first modification, and the second modification.

In the honeycomb structure 310, among the cells 320, cells 320 positioned in the central part 316 of the cell group 328 in the channel cross section direction have different sizes from those of the cells 320 positioned near the end 318. More specifically, the cells 320 positioned near the end 318 have larger channel cross sectional areas than the cells 320 positioned in the central part 316. The cells 320 positioned near the end 318 also have larger channel lengths between the incoming end 312 and the outgoing end 314 than the cells 320 positioned in the central part 316.

In other words, the curvatures of the incoming end 312 and the outgoing end 314 of the honeycomb structure 310 according to the third modification are smaller than the incoming end 12 and the outgoing end 14 according to the embodiment, the first modification, and the second modification. Furthermore, setting the curvature of the incoming end 312 smaller than the outgoing end 314 in the honeycomb structure 310 suppress the dead space 332 between the cell 320 at the end 318 and the cell 320 at the end 318 of an adjacent cell group 328. In this manner, it is possible to suppress curving, which is caused by a flow of the fluid F near the end 318 of the cell group 328 in the honeycomb structure 310, of other main flows of the fluid F.

The honeycomb structure 310 also includes a straightening vane 340 projecting from the incoming end 312, in a dead space 332 that is the space surrounded by the separator walls 322 of the cells 320 at the ends 318 of the adjacent cell groups 328. When the receiving surface 342 of the straightening vane 340 receives the fluid F, it possible to further suppress curving, which is caused by a flow of the fluid F near the end 318 of the cell group 328 in the honeycomb structure 310, of other main flows of the fluid F, thereby suppressing the pressure loss.

### Fourth Modification

A configuration of a honeycomb structure 410 according to a fourth modification will now be explained. FIG. 12 is a cross-sectional view illustrating the honeycomb structure 410 according to the fourth modification. In the honeycomb structure 410 illustrated in FIG. 12, the right half is illustrated with the separator walls 422 of the cells 420 omitted, and indicates the directions of the fluid F passing through the cells 420.

The honeycomb structure 410 according to the fourth modification has an incoming end 412 of a concave shape and an outgoing end 414 of a convex shape. The honeycomb structure 410 according to the fourth modification includes a plurality of cells 420 and a straightening vane 440 instead of the cells 320 and the straightening vane 340, which is difference from the honeycomb structure 310 according to the third modification. Adjacent cells 420 of the cells 420 are separated from one another by the separator walls 422, in the same manner as the cells 20, 220, 320 in the embodiment, the first modification, the second modification, and the third modification.

The cell 420 has an incoming opening 424 that opens to the incoming end 412, and an outgoing opening 426 that opens to the outgoing end 414. The honeycomb structure 410 is provided with a plurality of cell groups 428 connected to each other in a fan-like cross section so that the cell groups 428 are arranged continuously, in the same manner as in the honeycomb structure 10, 110, 210, 310 according to the embodiment, the first modification, the second modification, and the third modification.

In the honeycomb structure 410, among the cells 420, cells 420 positioned in the central part 416 of the cell group 428 in the channel cross section direction have different sizes from those of the cells 420 positioned near the end 418. More specifically, the cells 420 positioned near the end 418 have larger channel cross sectional areas than the cells 420 positioned in the central part 416. Furthermore, the cells 420 positioned near the end 418 have larger channel lengths from the incoming end 412 to the outgoing end 414 than the cells 420 positioned in the central part 416. The cells 420 positioned in the central part 416 also have a straight shape where the shape and the area of the channel cross section from the incoming end 412 to the outgoing end 414 are constant.

In other words, in the fourth modification, the central part 416 of the cell group 428 is flat in the honeycomb structure 410. In this manner, with the cell group 428 having a convex shape on the outgoing end 414 side as a whole, in the same manner as the honeycomb structure 10 according to the embodiment, the honeycomb structure 410 can suppress the pressure loss of the fluid F and can also be provided in a shape suitable for a structure to which the honeycomb structure 10 is applied and a surrounding environment.

The honeycomb structure 410 also includes a straightening vane 440 projecting from the incoming end 412, in a dead space 432 that is the space surrounded by the separator walls 422 of the cells 420 at the ends 418 of the adjacent cell groups 428. When the receiving surface 442 of the straightening vane 440 receives the fluid F, it is possible to suppress curving, which is caused by a flow of the fluid F near the end 418 of the cell group 428 in the honeycomb structure 410, of other main flows of the fluid F, thereby suppressing the pressure loss.

### Fifth Modification

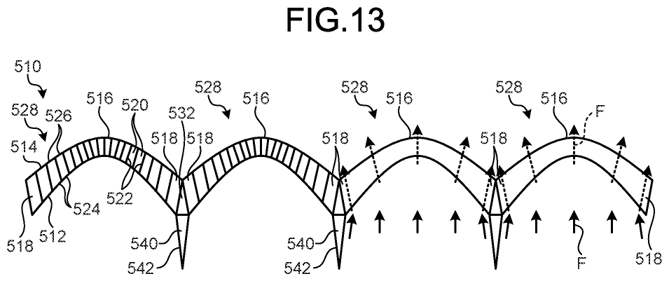

A configuration of a honeycomb structure 510 according to a fifth modification will now be explained. FIG. 13 is a cross-sectional view illustrating the honeycomb structure 510 according to the fifth modification. In the right half of the honeycomb structure 510 illustrated in FIG. 13, the separator walls 522 of the cells 520 are not illustrated, but the directions in which the fluid F passing through the cells 520 flows are indicated.

The honeycomb structure 510 according to the fifth modification has an incoming end 512 having a concave shape, and an outgoing end 514 having a convex shape. The honeycomb structure 510 according to the fifth modification is different from the honeycomb structure 310 according to the third modification in including a plurality of cells 520 and a straightening vane 540, instead of the cells 320 and the straightening vane 340. Adjacent cells 520 of the cells 520 are separated from one another by the separator walls 522, in the same manner as in the cells 20, 220, 320, 420 in the embodiment, the first modification, the second modification, the third modification, and the fourth modification.

The cell 520 has an incoming opening 524 that opens to the incoming end 512, and an outgoing opening 526 that opens to the outgoing end 514. The honeycomb structure 510 is provided with a plurality of cell groups 528 connected to each other in a fan-like cross section so that the cell groups 528 are arranged continuously, in the same manner as in the honeycomb structures 10, 110, 210, 310, 410 according to the embodiment, the first modification, the second modification, the third modification, and the fourth modification.

In the honeycomb structure 510, among the cells 520, cells 520 positioned in the central part 516 of the cell group 528 in the channel cross section direction have different sizes from those of the cells 520 positioned near the end 518. More specifically, the cells 520 positioned near the end 518 have larger channel cross sectional areas than the cells 520 positioned in the central part 516. Furthermore, the cells 520 positioned near the end 518 have larger channel lengths between the incoming end 512 and the outgoing end 514, than the cells 520 positioned in the central part 516.

In the fifth modification, the curvatures of the incoming end 512 and the outgoing end 514 of the honeycomb structure 510 are greater than the incoming end 12, 312 and the outgoing end 14, 314 according to the embodiment, the first modification, the second modification, and the third modification. In this manner, with the cell group 528 having a convex shape on the outgoing end 514 side as a whole, in the same manner as the honeycomb structure 10 according to the embodiment, the honeycomb structure 510 can suppress the pressure loss of the fluid F and can also be provided in a shape suitable for a structure to which the honeycomb structure 510 is applied and a surrounding environment. Specifically, by increasing the curvatures of the incoming end 512 and the outgoing end 514, the size in a direction intersecting with a direction in which the fluid F flows (the right-left direction in FIG. 13) can be suppressed. In this manner, the honeycomb structure 510 can be installed in a location with a limited installation space.

The honeycomb structure 510 also includes a straightening vane 540 projecting from the incoming end 512, in a dead space 532 that is the space surrounded by the separator walls 522 of the cells 520 at the ends 518 of the adjacent cell groups 528. When the receiving surface 542 of the straightening vane 540 receives the fluid F, it is possible to suppress curving, which is caused by a flow of the fluid F near the end 518 of the cell group 528 in the honeycomb structure 510, of other main flows of the fluid F, thereby suppressing the pressure loss.

### Actions and Effects Achieved by Embodiments

A method for manufacturing the honeycomb structure 10, 110, 210, 310, 410, 510 and the honeycomb structure 10, 110, 210, 310, 410, 510 according to the embodiments is recognized as follows, for example.

The honeycomb structure 10, 110, 210, 310, 410, 510 according to a first aspect includes the incoming end 12, 312, 412, 512 having a concave shape, the outgoing end 14, 314, 414, 514 having a convex shape, and a plurality of the cells 20, 220, 320, 420, 520 each having a polygonal cross section and serving as a channel for the fluid F, the channel extending from the incoming end 12, 312, 412, 512 to the outgoing end 14, 314, 414, 514. The cells 20, 220, 320, 420, 520 are separated from one another by the separator walls 22, 222, 322, 422, 522, and at least some of the cells 20, 220, 320, 420, 520 among the cells 20, 220, 320, 420, 520 increase an area of the channel cross section perpendicular to the longitudinal direction of the cells 20, 220, 320, 420, 520 from the incoming end 12, 312, 412, 512 toward the outgoing end 14, 314, 414, 514.

The honeycomb structure 10, 110, 210, 310, 410, 510 according to the first aspect has the channel area that increases in the direction from the incoming end 12, 312, 412, 512 toward the outgoing end 14, 314, 414, 514. In the honeycomb structure 10, 110, 210, 310, 410, 510, because the flow velocity of the fluid F passing through the cells 20, 220, 320, 420, 520 decreases as the channel area increases, the pressure loss is suppressed. In other words, because the honeycomb structure 10, 110, 210, 310, 410, 510 has the outgoing end 14, 314, 414, 514 having a convex shape, the pressure loss can be suppressed compared with the honeycomb structure 910 in which the incoming end 912 and the outgoing end 914 are flat. Therefore, it is possible to suppress the pressure loss while maintaining the shielding performance.

In the honeycomb structure 10, 110, 210, 310, 410, 510 according to a second aspect, a plurality of the cells 20, 220, 320, 420, 520 and the adjacent cells 20, 220, 320, 420, 520 with separator walls 22, 222, 322, 422, 522 interposed therebetween are provided so as to share the separator walls 22, 222, 322, 422, 522. In this manner, electrical connection in a portion where the adjacent cells 20, 220, 320, 420, 520 are joined is good compared with the conventional honeycomb structure where the cells share no separator wall with each other, which can improve the shielding performance for preventing the entry of the high EMPs.

The honeycomb structures 110, 210, 310, 410, 510 according to a third aspect include the straightening vanes 40, 340, 440, 540 projecting from the separator walls 22, 222, 322, 422, 522 that are not shared by cells 20, 220, 320, 420, 520 adjacent to each other toward the incoming ends 12, 312, 412, 512. The straightening vane 40, 340, 440, 540 receives the fluid F, to prevent the fluid F from flowing into the dead space 32, 332, 432, 532 that is the space surrounded by the separator walls 22, 222, 322, 422, 522 not shared by any adjacent cells 20, 220, 320, 420, 520. In this manner, it is possible to suppress curving, which is caused by a flow of the fluid F near the ends 18, 318, 418, 518 in the honeycomb structures 110, 210, 310, 410, 510, of other main flows of the fluid F.

In the honeycomb structure 10, 110, 210, 310, 410, 510 according to a fourth aspect, the separator walls 22, 222, 322, 422, 522 have a uniform thickness. In this manner, the inner walls of the cells 20, 220, 320, 420, 520 become flat, so that it becomes possible to suppress the pressure loss of the fluid F passing through the cells 20, 220, 320, 420, 520.

In the honeycomb structure 10, 110, 210, 310, 410, 510 according to a fifth aspect, the cells 20, 220, 320, 420, 520 have a channel cross section with a regular hexagonal shape. With this configuration, because the high EMPs do not diffusely reflect on the separator walls 22, 222, 322, 422, 522 facing each other in the cells 20, 220, 320, 420, 520, the shielding performance can be improved.

In the honeycomb structure 10, 110, 210, 310, 410, 510 according to a sixth aspect, the cells 20, 220, 320, 420, 520 have an increase ratio of a width of the channel cross section from the incoming end 12, 312, 412, 512 to the outgoing end 14, 314, 414, 514 that is equal to or more than one and equal to or less than two. Because the flow velocity of the fluid F passing through the cells 20, 220, 320, 420, 520 decreases as the channel area increases, it is possible to reduce the pressure loss, thereby suppressing the pressure loss while maintaining the shielding performance.

The honeycomb structure 110 according to a seventh aspect has a dome shape in which the incoming end 12 has a concave spherical surface and the outgoing end 14 has a convex spherical surface. In other words, the fluid F passing through the cells 20 of the honeycomb structure 110 flow in radially spreading directions. Because the flow velocity of the fluid F passing through the cells 20 decreases as the channel area increases, it is possible to suppress the pressure loss, thereby suppressing the pressure loss while maintaining the shielding performance.

In the honeycomb structure 210, 310, 410, 510 according to an eighth aspect, among the cells 220, 320, 420, 520, the cells 220, 320, 420, 520 positioned at the end 18, 318, 418, 518 in the channel cross section direction have larger channel cross sectional areas than the cells 220, 320, 420, 520 positioned in the central part 16, 316, 416, 516 in the channel cross section direction. In the honeycomb structure 210, 310, 410, 510 having the outgoing end 14, 314, 414, 514 protruding in a concave shape, the fluid F becomes collected at the central part 16, 316, 416, 516, and does not tend to flow into the end 18, 318, 418, 518. By setting the channel cross sectional area of the cells 220, 320, 420, 520 near the end 18, 318, 418, 518 larger than the central part 16, 316, 416, 516, it is possible to suppress the difference in the flow velocities of the fluid F on the incoming end 12, 312, 412, 512. In this manner, because it is possible to cause the fluid F to flow at a constant velocity across the entire honeycomb structure 210, 310, 410, 510, the pressure loss can be suppressed.

In the honeycomb structure 310, 410, 510 according to a ninth aspect, among the cells 320, 420, 520, cells 320, 420, 520, the cells 320, 420, 520 positioned at the end 318, 418, 518 in the longitudinal direction have larger lengths than the cells 320, 420, 520 positioned in the central part 316, 416, 516 in the channel cross section direction. In this manner, the honeycomb structure 310, 410, 510 keeps the curvature of the incoming end 312, 412, 512 smaller than that of the outgoing end 314, 414, 514, and keeps the dead space 332, 432, 532 that is the space surrounded by the separator walls 322, 422, 522 not shared by any adjacent cells 320, 420, 520 small. In this manner, it is possible to suppress curving, which is caused by a flow of the fluid F near the end 318, 418, 518 of the honeycomb structure 310, 410, 510, of other main flows of the fluid F.

The honeycomb structure 10, 110, 210, 310, 510 according to a tenth aspect, the incoming end 12, 312, 512 and the outgoing end 14, 314, 514 are curved as a whole in a direction of the side of the incoming end 12, 312, 512. In other words, the fluid F passing through the cells 20, 220, 320, 520 of the honeycomb structure 10, 110, 210, 310, 510 flows in radially spreading directions. Because the flow velocity of the fluid F passing through the cells 20, 220, 320, 520 decreases as the channel area increases, it is possible to suppress the pressure loss, thereby suppressing the pressure loss while maintaining the shielding performance.

In the honeycomb structure 410 according to an eleventh aspect, among the cells 420, the cells 420 positioned in the central part of the channel cross section direction have the cross sections the shape and area of which are constant from the incoming end 412 to the outgoing end 414. In this manner, the central part 416 of the honeycomb structure 410 is kept flat. Therefore, because the honeycomb structure 410 as a whole has a shape that is convex toward the outgoing end 414, the honeycomb structure 410 can suppress the pressure loss of the fluid F and can also be provided in a shape suitable for a structure to which the honeycomb structure 410 is applied and a surrounding environment.

The honeycomb structure 10, 110, 210, 310, 410, 510 according to a twelfth aspect is a honeycomb structure 10, 110, 210, 310, 410, 510 including an assembly of a plurality of polygonal prism-shaped cells (the cell 20, 220, 320, 420, 520) each having a polygonal cross section in which a passage in the longitudinal direction is provided. In the honeycomb structure 10, 110, 210, 310, 410, 510, a side face of one of the polygonal prism-shaped cells and a side face of another one of the adjacent polygonal prism-shaped cells integrally form a separator wall 22, 222, 322, 422, 522; at least some of the polygonal prism-shaped cells among the plurality of polygonal prism-shaped cells have a cross sectional area having a width increasing from one ends (the incoming end 12, 312, 412, 512) toward the other ends (the outgoing end 14, 314, 414, 514) of the polygonal prism-shaped cells in the longitudinal direction; and the surface of the one end and the surface of the other end of the assembly in the longitudinal direction are curved toward the direction opposite to the direction in which the width increases.

The honeycomb structure 10, 110, 210, 310, 410, 510 according to the twelfth aspect achieves a good electrical connection in a portion where the adjacent polygonal prism-shaped cells are joined compared with the conventional honeycomb structure in which one side face of the polygonal prism-shaped cell is not integrated with that of another adjacent polygonal prism-shaped cell, which can improve the shielding performance for preventing the entry of the high EMPs. Furthermore, the fluid F passing through the polygonal prism-shaped cells flows in radially spreading directions, and the flow velocity thereof decreases as the channel area increases. Therefore, it is possible to reduce the pressure loss, thereby suppressing the pressure loss while maintaining the shielding performance.

The honeycomb structure 10, 110 according to a thirteenth aspect is the shield structure 50, 150 provided so as to close an opening in a given facility, and is intended to prevent entry of high EMPs from the opening. The honeycomb structure 10, 110 can be built into any desired shape by adjusting the width of the channel cross section, the channel length, and the increase ratio of the cells 20 across the range from the incoming end 12 to the outgoing end 14, and thus can be applied to an opening having a complicated shape.

The honeycomb structure 10 according to a fourteenth aspect is provided in such an orientation that the longitudinal directions of the cells 20 are inclined with respect to the direction in which the opening opens. Even when the direction of the flow of the fluid F is inclined with respect to the direction in which the opening opens in the manner described above, the honeycomb structure 10 can be provided in a shape suitable for a structure to which the honeycomb structure 10 is applied and a surrounding environment.

The honeycomb structure 110 according to a fifteenth aspect is provided in such a manner that a plurality of hexagonal structures each having the dome portion 152 are connected with the respective side faces of the hexagons connected to one another, the dome portion 152 having the incoming end 12 with a concave spherical surface and the outgoing end 14 with a convex spherical surface. In other words, the fluid F passing through the cells 20 in the dome portion 152 flows in radially spreading directions. Because the flow velocity of the fluid F passing through the cells 20 in the dome portion 152 decreases as the channel area increases, it is possible to suppress the pressure loss, thereby suppressing the pressure loss while maintaining the shielding performance.

In the honeycomb structure 110 according to a sixteenth aspect, cells each having a cross section the shape and area of which are constant from the incoming end 12 to the outgoing end 14 are arranged in a space surrounded by a plurality of the dome portions 152. By increasing the channel area in the dome portion 152 and arranging the straight cells in the space surrounded by the dome portion 152, it is possible to reduce the dead space, and to further suppress the pressure loss.

The honeycomb structure 110 according to a seventeenth aspect includes the straightening vane 40 that is provided in a ring-like shape along the end 18 of the dome portion 152, and that projects from the separator wall 22 toward the incoming end 12. In this manner, it is possible to suppress curving, which is caused by a flow of the fluid F near the end 18 of the dome portion 152, of other main flows of the fluid F.

In a method for manufacturing the honeycomb structure 10, 110, 210, 310, 410, 510 according to an eighteen aspect, the honeycomb structure 10, 110, 210, 310, 410, 510 is manufactured by additively laying layers on a protrusion provided on the side of the outgoing end 14, 314, 414, 514 as a base, toward the incoming end 12, 312, 412, 512, using a 3D printer. In other words, by setting the side with a larger cross sectional area as a lower layer, the honeycomb structure 10, 110, 210, 310, 410, 510 can be manufactured stably. Furthermore, the raft can be removed easily after the manufacture.

In a method for manufacturing the honeycomb structure 10, 110, 210, 310, 410, 510 according to a nineteenth aspect, the honeycomb structure 10, 110, 210, 310, 410, 510 is manufactured by extrusion. In this manner, the cells 20, 220, 320, 420, 520 can be manufactured integrally, so that it is possible to form the separator walls 22, 222, 322, 422, 522 separating the adjacent cells 20, 220, 320, 420, 520, as the walls shared between the adjacent cells 20, 220, 320, 420, 520. Therefore, a good electrical connection is achieved in a portion where the adjacent cells 20, 220, 320, 420, 520 are joined, so that the shielding performance for preventing the entry of the high EMPs can be improved.

Some embodiments of the present invention have been explained above, but none of the descriptions in these embodiments is not intended to limit the scope of the embodiments in any way. Furthermore, the shield structure 50, 150 for preventing the entry of the high EMP has been explained as an example in the application modes, but the honeycomb structure 10, 110, 210, 310, 410, 510 according to the embodiment may also be applied to a heat exchanger, for example.

### REFERENCE SIGNS LIST

10, 110, 210, 310, 410, 510, 910 Honeycomb structure
12, 312, 412, 512, 912 Incoming end
14, 314, 414, 514, 914 Outgoing end
16, 316, 416, 516 Central part
18, 318, 418, 518 End
20, 220, 320, 420, 520, 920 Cell
22, 222, 322, 422, 522 Separator wall
24, 224, 324, 424, 524 Incoming opening
26, 226, 326, 426, 526 Outgoing opening
28, 228, 328, 428, 528 Cell group
30, 930 Channel area
32, 332, 432, 532 Dead space
40, 340, 440, 540 Straightening vane
42, 342, 442, 542 Receiving surface
50, 150 Shield structure
60 Frame
152 Dome portion
154 Inter-dome portion
L Length
W1, W2 Width
H1, H2 Distance
θ Increasing angle
F Fluid
φ Straightening angle

1. A honeycomb structure comprising:
an incoming end having a concave shape;
an outgoing end having a convex shape; and
a plurality of cells each having a polygonal cross section and serving as a channel for a fluid, the channel extending from the incoming end to the outgoing end, wherein
the plurality of cells are separated from each other by separator walls, and
at least one of the plurality of cells has an area of a channel cross section perpendicular to a longitudinal direction, the area increasing from the incoming end toward the outgoing end.

2. The honeycomb structure according to claim 1, wherein, the plurality of cells includes adjacent cells that share the separator wall interposed therebetween.

3. The honeycomb structure according to claim 1, further comprising a straightening vane projecting from the separator wall not shared by adjacent cells of the plurality of cells toward the incoming end.

4. The honeycomb structure according to claim 1, wherein the separator walls have a uniform thickness.

5. The honeycomb structure according to claim 1, wherein each of the cells has a channel cross section with a regular hexagonal shape.

6. The honeycomb structure according to claim 1, wherein each of the cells has an increase ratio of a width of the channel cross section from the incoming end to the outgoing end, the increase ratio being equal to or more than one and equal to or less than two.

7. The honeycomb structure according to claim 1, wherein the honeycomb structure has a dome shape in which the incoming end has a concave spherical surface and the outgoing end has a convex spherical surface.

8. The honeycomb structure according to claim 1, wherein, among the plurality of cells, a cell positioned at an end in a channel cross section direction has a larger channel cross sectional area than a cell positioned in a central part in the channel cross section direction.

9. The honeycomb structure according to claim 1, wherein, among the plurality of cells, a cell positioned at an end in a channel cross section direction has a larger length in a longitudinal direction than the cell positioned in a central part in the channel cross section direction.

10. The honeycomb structure according to claim 1, wherein the incoming end and the outgoing end are curved as a whole toward the incoming end.

11. The honeycomb structure according to claim 1, wherein, among the plurality of cells, a cell positioned in a central part in a channel cross section direction has a cross section whose shape and area are constant from the incoming end to the outgoing end.

12. A honeycomb structure made from an assembly of a plurality of polygonal prism-shaped cells having a polygonal cross section in which a passage in a longitudinal direction is provided, wherein
a side face of one of the plurality of polygonal prism-shaped cells and a side face of another polygonal prism-shaped cell adjacent to the one of the plurality of polygonal prism-shaped cells integrally form a separator wall,
at least one of the plurality of polygonal prism-shaped cells has an area of the cross section, the area increasing from one end toward another end of the at least one of the plurality of polygonal prism-shaped cells in the longitudinal direction, and
a surface of the one end and a surface of the other end of the assembly in the longitudinal direction are curved toward a direction opposite to a direction in which the area increases.

13. The honeycomb structure according to claim 1, wherein the honeycomb structure is a shield structure that is provided so as to close an opening in given facility, and that is intended to prevent entry of a high electromagnetic pulse through the opening.

14. The honeycomb structure according to claim 13, wherein the honeycomb structure is provided in such an orientation that longitudinal directions of the plurality of cells are inclined with respect to a direction in which the opening opens.

15. The honeycomb structure according to claim 13, wherein the honeycomb structure is provided in such a manner that a plurality of hexagonal structures each having a dome portion are connected to one another with the respective side faces of the hexagons connected to one another, the dome portion having the incoming end with a concave spherical surface and having the outgoing end with a convex spherical surface.

16. The honeycomb structure according to claim 15, wherein a cell having a cross section whose shape and area are constant from the incoming end to the outgoing end is arranged in a space surrounded by the dome portions.

17. The honeycomb structure according to claim 15, further comprising a straightening vane that is provided in a ring-like shape along an end of the dome portion and that projects from the separator wall toward the incoming end.

18. A method for manufacturing the honeycomb structure according to claim 1, wherein a 3D printer additively lays layers, with a protrusion that is to be on a side of the outgoing end as a base, toward the incoming end, so as to manufacture the honeycomb structure.

19. A method for manufacturing the honeycomb structure according to claim 1, wherein the honeycomb structure is manufactured by extrusion.

20. A method for manufacturing the honeycomb structure according to claim 12, wherein a 3D printer additively lays layers, with a protrusion that is to be on a side of the outgoing end as a base, toward the incoming end, so as to manufacture the honeycomb structure.

21. A method for manufacturing the honeycomb structure according to claim 12, wherein the honeycomb structure is manufactured by extrusion.
